(19) United States
(12) Patent Application Publication
(10) Pub. No.: US 2026/0365207 A1
(43) Pub. Date: Nov. 19, 2026

(54) Transport Facility

(71) Applicant: Daifuku Co., Ltd., Osaka-shi (JP)

(72) Inventors: Tomotaka Kinugawa, Hinocho (JP); Yuki Kosugi, Hinocho (JP); Jongwon Song, Hinocho (JP)

(21) Appl. No.: 19/679,882

(22) Filed: May 18, 2026

(30) Foreign Application Priority Data
May 19, 2025 (JP) 2025-083582

(51) Int. Cl. B61L 25/02; B61L 27/04; H10P 72/30

(52) U.S. Cl. CPC B61L 25/025; B61L 27/04; H10P 72/3206; H10P 72/3214; H10P 72/3221

(57) ABSTRACT

A transport facility includes a training process wherein a transport vehicle learns a transfer position corresponding to a transfer area. A control system in the transport facility specifies a learning target transfer area associated with a target position, causes the transport vehicle to travel to a target holder and perform an adjustment operation for adjusting a stop position of the transport vehicle based on a detection device detecting a detection target after a location information obtaining device obtains the location information of the target position, causes the transport vehicle to stop traveling in response to a detection state entering a preset state. The detection state is a state of the detection device detecting the detection target and records, as the transfer position, a position based on a first stop position at which the transport vehicle has stopped in response to the detection state entering the preset state.

### CROSS-REFERENCE TO RELATED APPLICATION

This application claims priority to Japanese Patent Application No. 2025-083582 filed May 19, 2025, the disclosure of which is hereby incorporated by reference in its entirety.

### BACKGROUND OF THE INVENTION

### Field of the Invention

The present invention relates to a transport facility including a transport vehicle that transports articles, a travel path along which the transport vehicle travels, a transfer area to and from which the transport vehicle stopped at a transfer position on the travel path transfers articles, and a control system that controls the transport vehicle.

### Description of Related Art

An example of such a transport facility is described in Japanese Unexamined Patent Application Publication No. 2018-41409 (JP 2018-414091). In the background described hereafter, reference signs in parentheses are the reference signs in Patent Literature 1. The transport facility described in JP 2018-41409 includes a transport vehicle (1) that travels along a travel path to transport an article (W), a processing device (3), a storage shelf (4), and a controller (H) that controls the transport vehicle (1). The travel path has a first stop position (P1) at which the transport vehicle (1) stops to transfer the article (W) to and from the storage shelf (4) and a second stop position (P2) at which the transport vehicle (1) stops to transfer the article (W) to and from a mount (5) included in the processing device (3). Detectable members (T1, T3) storing address information are disposed at the first stop position (P1) and the second stop position (P2). The transport vehicle (1) includes detection devices (S1, S2) that detect the detectable members (T1, T3). The controller (H) causes the transport vehicle (1) to stop at the first stop position (P1) corresponding to the storage shelf (4) or the second stop position (P2) corresponding to the mount (5) based on detection information of the detectable members (T1, T3) obtained from the detection devices (S1, S2).

To cause a transport vehicle to stop at a transfer position for transferring articles to and from a transfer area such as a mount or storage shelves, the transfer position corresponding to the transfer area is to be determined. With the technique described in JP 2018-41409, location information holders storing location information (the detectable members storing address information in JP 2018-41409) are disposed at transfer positions (the first stop position and the second stop position in JP 2018-41409), and thus the position of a location information holder detected by the transport vehicle can be determined as the transfer position. In this case, the location information holders are to be aligned with transfer positions with accuracy high enough to allow determination of an appropriate transfer position. However, disposing the location information holders in such a manner may not be easy. Transport facilities typically have multiple transfer areas. Multiple location information holders are thus to be aligned with the transfer positions corresponding to the respective transfer areas, and the operation of disposing the location information holders tends to be complicated.

### SUMMARY OF THE INVENTION

Techniques are awaited for determining the appropriate transfer position corresponding to a transfer area when no location information holder is aligned with the transfer position.

A transport facility according to an aspect of the present disclosure includes a transport vehicle that transports an article, a travel path along which the transport vehicle travels, a transfer area to and from which the transport vehicle stopped at a transfer position on the travel path transfers the article, a control system that controls the transport vehicle, and a plurality of location information holders arranged at discrete locations along the travel path. The plurality of location information holders hold location information of positions on the travel path. The transport vehicle includes a location information obtaining device that obtains the location information from the plurality of location information holders, and a detection device that detects a detection target disposed on the transfer area. One of the plurality of location information holders is a target holder. The location information held by the target holder indicates a target position. In a training process to cause the transport vehicle to learn the transfer position corresponding to the transfer area, the control system specifies a learning target transfer area in a manner associated with the target position, causes the transport vehicle to travel to the target holder and perform an adjustment operation for adjusting a stop position of the transport vehicle based on the detection device detecting the detection target after the location information obtaining device obtains the location information of the target position, causes the transport vehicle to stop traveling in response to a detection state entering a preset state, the detection state being a state of the detection device detecting the detection target, and records, as the transfer position, a position based on a first stop position that is a position at which the transport vehicle has stopped in response to the detection state entering the preset state.

This structure can determine the appropriate transfer position through the training process when no location information holder is aligned with the transfer position corresponding to the transfer area. More specifically, in the training process, after the location information obtaining device obtains location information of the target position, the detection device detects the detection target disposed on the transfer area to locate the transfer area. The adjustment operation is then performed to adjust the stop position of the transport vehicle to cause the transport vehicle to stop traveling based on the detection state of the detection target detected by the detection device entering the preset state. This allows determining and recording the position based on this stop position, which is the first stop position, as the transfer position. When the transport vehicle transfers articles to and from a transfer area, the transport vehicle can determine the transfer position corresponding to the transfer area based on recording results obtained through the training process.

As described above, this structure can determine the appropriate transfer position corresponding to a transfer area when no location information holder is aligned with the transfer position.

Further aspects and features of the transport facility will be apparent from embodiments described below with reference to the drawings.

### BRIEF DESCRIPTION OF THE DRAWINGS

FIG. 1 is a diagram of a transport vehicle according to a first embodiment.

FIG. 2 is a diagram of an aspect of a training process in the first embodiment.

FIG. 3 is a diagram of an aspect of the training process in the first embodiment.

FIG. 4 is a graph showing an example trend of traveling speed in the training process in the first embodiment.

FIG. 5 is a diagram of an aspect of the training process in the first embodiment.

FIG. 6 is a control block diagram in the first embodiment.

FIG. 7 is a diagram illustrating a training process according to a second embodiment.

FIG. 8 is a diagram of an aspect of the training process in the second embodiment.

FIG. 9 is a diagram of an aspect of the training process in the second embodiment.

FIG. 10 is a diagram of an aspect of the training process in the second embodiment.

FIG. 11 is a diagram of an aspect of a training process according to a third embodiment.

FIG. 12 is a diagram of an aspect of the training process in the third embodiment.

### DESCRIPTION OF THE INVENTION

### First Embodiment

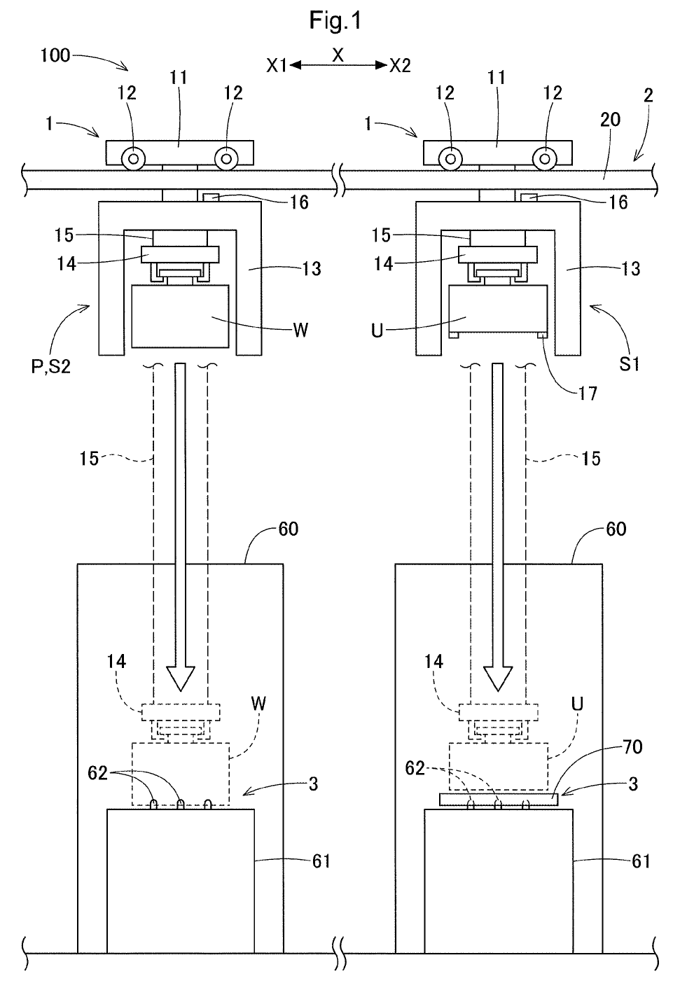

A transport facility according to a first embodiment will be described with reference to the drawings (FIGS. 1 - 6). Each drawing shows components in a simplified manner as appropriate. The actual shapes and proportions may or may not be drawn to scale.

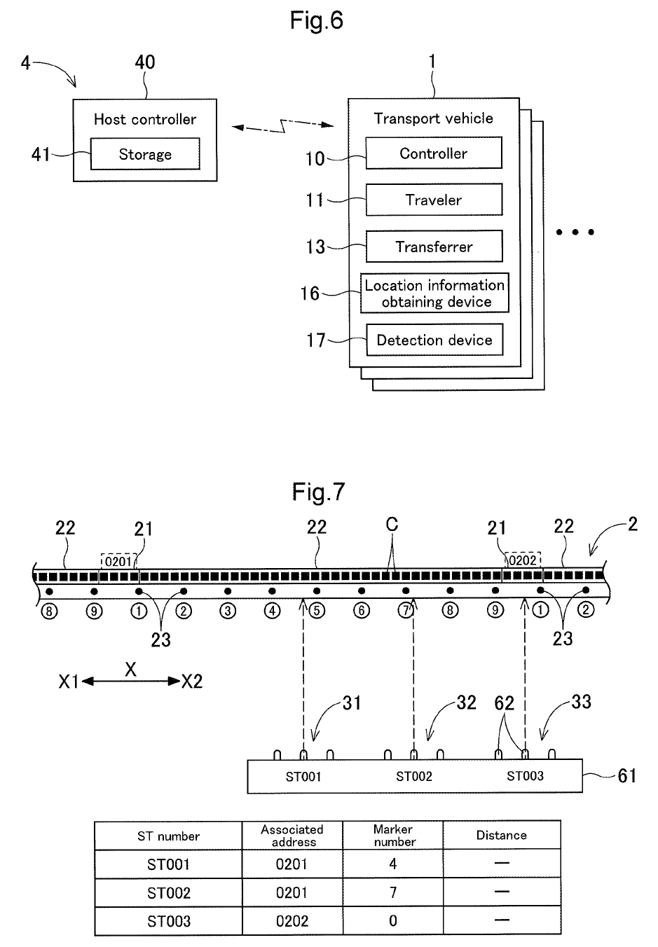

As shown in FIG. 1, a transport facility 100 includes a transport vehicle 1 that transports an article W, a travel path 2 along which the transport vehicle 1 travels, a transfer area 3 to and from which the transport vehicle 1 stopped at a transfer position P on the travel path 2 transfers the article W, and a control system 4 (refer to FIG. 6) that controls the transport vehicle 1. In the present embodiment, the transport facility 100 includes multiple transport vehicles 1. The control system 4 controls the multiple transport vehicles 1. The article W is, for example, a front-opening unified pod (FOUP) containing semiconductor wafers.

The transfer area 3 is the source or the destination of an article W. The transport vehicles 1 are each assigned to a transport task specifying the source and the destination of an article W. The transport vehicle 1 assigned to the transport task travels to the source specified in the transport task to receive the article W from the source, and then travels to the destination specified in the transport task to transfer the article W to the destination.

FIG. 1 shows an example of the transfer area 3. This example is a platform 61 (a load port) in a processing device 60 that processes an article W (or the contents of an article W). The transfer area 3 is not limited to this example but may include a transfer port for loading or unloading in a storage device that stores articles W or storage shelves that temporarily store articles W. The transfer port is, for example, defined by an inbound conveyor or an outbound conveyor.

The travel path 2 extends through the transfer area 3. The direction along the travel path 2 is referred to as a travel direction X. The transport vehicles 1 travel forward to a downstream side X2 along the travel path 2, whereas the transport vehicles 1 travel backward to an upstream side X1 along the travel path 2. The transport vehicles 1 normally travel forward along the travel path 2 but may travel backward during, for example, an adjustment operation (described later).

As shown in FIG. 1, the travel path 2 in the present embodiment is defined by rails 20. In the present embodiment, the rails 20 are hung from the ceiling. In the present embodiment, the transport vehicles 1 are ceiling-hung transport vehicles that travel along the travel path 2 defined along the ceiling. The travel path 2 may be defined on, for example, the floor surface, rather than along the ceiling. The travel path 2 may be defined without using the rails 20. For example, the travel path 2 may be defined by a detectable member (e.g., magnetic tape) laid continuously on, for example, the floor surface. The travel path 2 may also be defined as connected detectable members (e.g., two-dimensional codes or wireless tags) intermittently installed on, for example, the floor surface. In this case, each transport vehicle 1 includes a detection device that detects the detectable members. In this manner, the transport vehicles 1 may be trackless transport vehicles, rather than tracked transport vehicles. The travel path 2 may be physically or virtually defined.

As shown in FIG. 1, each transport vehicle 1 includes a traveler 11 and a transferrer 13 connected to the traveler 11. In the present embodiment, the transferrer 13 is disposed under the traveler 11 and connected to the traveler 11. In this example, the transferrer 13 is disposed under the traveler 11 with the rails 20 positioned between them.

The traveler 11 includes multiple travel wheels 12 that roll on the rails 20. At least one of the multiple travel wheels 12 is rotated by an unillustrated drive source (e.g., an electric motor such as a servomotor), causing the traveler 11 to travel along the rails 20.

The transferrer 13 transfers articles W to and from transfer areas 3. The transport vehicle 1 (specifically, the transferrer 13) includes a holder 14 that holds an article W. In the present embodiment, the holder 14 holds an article W by supporting a flange formed on an upper part of the article W. The holder 14 is driven by an unillustrated drive source (e.g., an electric motor such as a servomotor) to perform a holding operation of holding the article W and a releasing operation of releasing the article W. The holding operation and the releasing operation are performed with the holder 14 placed at a transfer height (described later).

In the present embodiment, the transferrer 13 can lift and lower the holder 14 relative to the traveler 11. More specifically, the transferrer 13 includes an unillustrated roller (e.g., a drum) and a wound member 15 windable around and unwindable from the roller. With the holder 14 hung from the wound member 15, the transferrer 13 lifts and lowers the holder 14 by rotating the roller using an unillustrated drive source (e.g., an electric motor such as a servomotor). More specifically, the transferrer 13 lifts the holder 14 by winding the wound member 15 and lowers the holder 14 by unwinding the wound member 15. The figure on the left in FIG. 1 shows lowering the holder 14 holding an article W to transfer the article W to the transfer area 3. The figure on the right in FIG. 1 shows lowering the holder 14 holding a measurement unit U in place of the article W in a training process (described later).

When transferring articles W to and from transfer areas 3, the transport vehicle 1 travels to transfer positions P with the holder 14 placed at a travel height (the height of the holder 14 indicated by solid lines in the figure on the left in FIG. 1). The transfer positions P are positions at which articles W are transferred to and from the transfer areas 3 and correspond to the respective transfer areas 3. The transfer positions P are determined in the training process (described later).

The transport vehicle 1 at a transfer position P lifts and lowers the holder 14 to transfer an article W to and from a transfer area 3. More specifically, when transferring an article W to the transfer area 3, the transport vehicle 1 sequentially performs an operation of lowering the holder 14 holding the article W from the travel height to the transfer height (the height of the holder 14 indicated by dashed lines in the figure on the left in FIG. 1), an operation of releasing the article W from the holder 14, and an operation of lifting the holder 14 holding no article W from the transfer height to the travel height. The transfer height is set based on the height of the transfer area 3 and corresponds to the height of each transfer area 3. When receiving an article W from a transfer area 3, the transport vehicle 1 sequentially performs an operation of lowering the holder 14 holding no article W from the travel height to the transfer height, an operation of holding the article W with the holder 14, and an operation of lifting the holder 14 holding the article W from the transfer height to the travel height.

Although details are not described, the transferrer 13 may include, for example, a device that moves the holder 14 in the horizontal direction (the right-left direction of the transport vehicle 1) perpendicular to the travel direction X and a device that rotates the holder 14 about a vertical axis. For example, when a transfer area 3 is offset from the travel path 2 as viewed from above (as viewed in the vertical direction), the holder 14 is moved in the horizontal direction to a position that overlaps the transfer area 3 as viewed from above, and then the holder 14 is lifted or lowered to transfer the article W.

In the present embodiment, the transfer area 3 (the platform 61 in this example) has a positioning mechanism that positions an article W. In the present embodiment, the positioning mechanism includes positioning pins 62 (kinematic pins in this example) that engage with unillustrated recesses (e.g., recesses in the form of grooves) on the bottom of the article W. The positioning mechanism includes the same number of (three in this example) positioning pins 62 as recesses on the bottom of the article W and positions the article W by engaging each positioning pin 62 with the corresponding recess. The positioning mechanism may have any other structure. For example, the positioning mechanism may position an article W by engaging with the outer edge of a lower part of the article W.

As shown in FIG. 6, the control system 4 in the present embodiment includes a controller 10 included in each transport vehicle 1 and a host controller 40 that can communicate with each controller 10. The controllers (10, 40) each include an arithmetic processor such as a microcomputer and a peripheral circuit such as a memory. The functions of each controller are implemented by hardware such as the arithmetic processor cooperating with a program executed on the hardware.

The control system 4 described herein has technical features also applicable to a method for learning the transfer position P implemented by the control system 4 and programs that cause a computer to function as the control system 4. Such a learning method, programs, and a recording medium storing the programs (e.g., a computer-readable recording medium such as an optical disc or a flash memory) are also described herein.

The controller 10 controls the operation of the transport vehicle 1 including the controller 10 in response to an instruction from the host controller 40. For example, the host controller 40 assigns a transport task specifying the source and the destination of an article W to the transport vehicle 1. The controller 10 in the transport vehicle 1 assigned to a transport task controls the transport vehicle 1 to perform the transport task.

The control system 4 tracks the current positions of the multiple transport vehicles 1. In the present embodiment, each transport vehicle 1 determines its current position, and the host controller 40 obtains information indicating the current positions of the transport vehicles 1 from the transport vehicles 1.

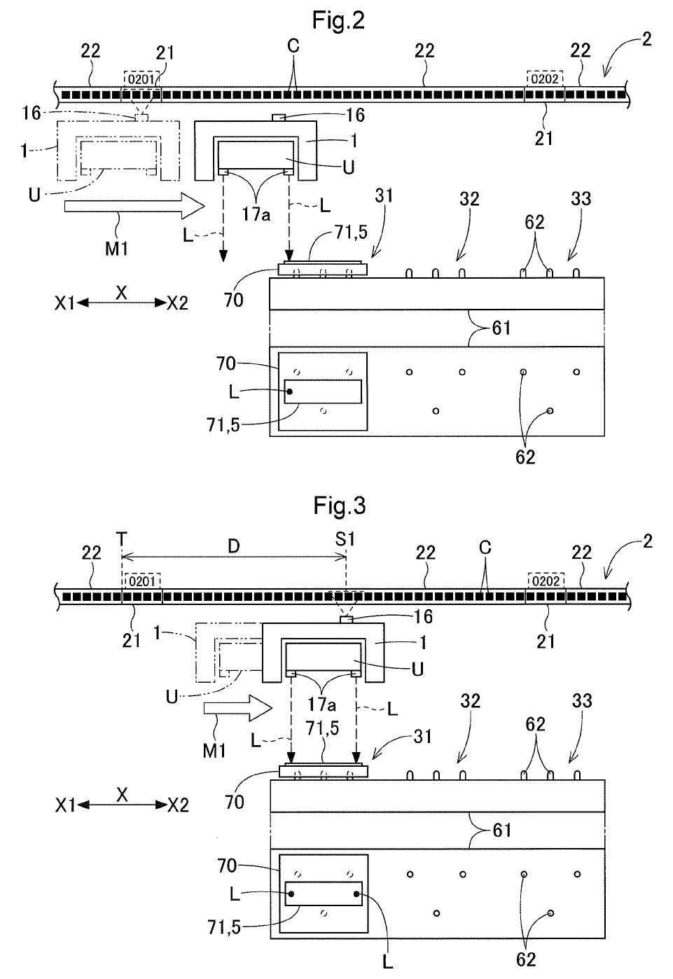

As shown in FIG. 2, multiple location information holders 21 storing location information of positions on the travel path 2 are arranged at discrete locations along the travel path 2. The location information holders 21 and a code tape 22 (described later) are arranged on, for example, the lower surface of the rails 20. In FIG. 2 and subsequent figures, the transport vehicle 1 is shown more simply than in FIG. 1. Each location information holder 21 holds information indicating the position (address) at which the location information holder 21 is disposed. FIG. 2 shows two location information holders 21. The location information holder 21 disposed on the upstream side X1 holds information indicating the address (0201) at which the location information holder 21 is disposed. The location information holder 21 disposed on the downstream side X2 holds information indicating the address (0202) at which the location information holder 21 is disposed. In the present embodiment, the location information holders 21 are codes C (identification codes) indicating location information. Although these codes C are two-dimensional codes in this example, the codes C may be, for example, one-dimensional codes. The location information holders 21 may not be marks such as the codes C but may be contactless electromagnetic media such as radio frequency identification (RFID) tags.

As shown in FIG. 1, the transport vehicle 1 includes a location information obtaining device 16 that obtains location information from location information holders 21. The location information obtaining device 16 being used corresponds to the type of the location information holders 21. In the present embodiment, the location information holders 21 are the codes C, and thus the location information obtaining device 16 is a code reader (a two-dimensional code reader in this example). In contrast, for example, when the location information holders 21 are RFID tags, the location information obtaining device 16 is a tag reader. The distance between two location information holders 21 adjacent to each other in the travel direction X is learned through, for example, a teaching operation that involves traveling of the transport vehicle 1.

The transport vehicle 1 determines its position on the travel path 2 by the location information obtaining device 16 sequentially obtaining the location information held by the multiple location information holders 21 arranged at discrete locations along the travel path 2. At a location on the travel path 2 at which no location information holder 21 is disposed, the transport vehicle 1 determines its position based on location information obtained from a location information holder 21 and the distance traveled after obtaining the location information. For example, the distance traveled by the transport vehicle 1 is measured using a travel distance detection device such as a rotary encoder.

In the present embodiment, as shown in FIG. 2, a code tape 22 displaying multiple codes C is disposed in each section of the travel path 2 in which no location information holders 21 are arranged. The code tape 22 displays the multiple codes C in the travel direction X sequentially (at intervals in this example). In the present embodiment, the codes C displayed on the code tape 22 have the same form as the codes C displayed on the location information holders 21. More specifically, the codes C displayed on the code tape 22 in this example are two-dimensional codes. The location information obtaining device 16 can thus obtain information from the codes C displayed on the code tape 22. The codes C displayed on the code tape 22 may have a different form from the codes C displayed on the location information holders 21. In this case, the transport vehicle 1 includes an information obtaining device that obtains information from the codes C displayed on the code tape 22 in addition to the location information obtaining device 16.

At a location on the travel path 2 at which no location information holder 21 is disposed, the transport vehicle 1 determines its position by obtaining information from the codes C displayed on the code tape 22. In the present embodiment, the transport vehicle 1 determines its position based on location information obtained from a location information holder 21 and information obtained from the codes C displayed on the code tape 22. More specifically, in the present embodiment, each code C displayed on the code tape 22 holds information indicating the distance from the code C to the location information holder 21 disposed on the upstream side X1. The transport vehicle 1 can thus obtain the distance information from the codes C displayed on the code tape 22 to determine the distance traveled after obtaining the location information from the location information holder 21. The transport vehicle 1 determines its position based on the location information obtained from the location information holder 21 and the travel distance determined as described above.

As described above, the transport vehicle 1 stopped at the transfer position P corresponding to a transfer area 3 transfers an article W to and from the transfer area 3. In the transport facility 100, no location information holder 21 is aligned with the transfer position P. In the transport facility 100, the stopping positions of the transport vehicle 1 are thus difficult to identify when an operation of transferring articles W to and from transfer areas 3 is learned during, for example, facility installation. In the present embodiment, the code tape 22 is disposed at each site on the travel path 2 at which no location information holder 21 is disposed. The code tape 22 is disposed over a predetermined section. The code tape 22 as well as the location information holders 21 is not aligned with the transfer position P.

In the transport facility 100, no location information holders 21 are aligned with the transfer position P as described above. However, the control system 4 performs the training process as described below to allow the transfer position P to be appropriately determined when no location information holders 21 are aligned with the transfer position P.

The transfer position P is determined using a detection target 5 disposed on the transfer area 3. The detection target 5 may be constantly disposed on the transfer area 3 or may be temporarily disposed on the transfer area 3 during the training process. In the present embodiment, the detection target 5 is temporarily disposed on the transfer area 3 during the training process. More specifically, as shown in the figure on the right in FIG. 1, a target plate 70 (a teaching plate) to be detected by the measurement unit U (described later) is disposed on the transfer area 3 during the training process. As shown in FIG. 2, a reflector 71 (a reflector in the form of a sheet in this example) is disposed on the upper surface of the target plate 70. The reflector 71 serves as the detection target 5. More specifically, the detection target 5 includes the reflector 71 disposed on the upper surface (the surface facing the transport vehicle 1) of the transfer area 3. The reflector 71 is formed from a material having a higher reflectance for sensing light L (described later) than a part of the upper surface of the target plate 70 on which no reflector 71 is disposed. FIG. 2 and subsequent figures show a top view of the platform 61 below a side view of the platform 61.

As shown in the figure on the right in FIG. 1, the target plate 70 disposed on the transfer area 3 is positioned by the above positioning mechanism (the positioning pins 62 in the present embodiment). More specifically, the positioning pins 62 engage with the unillustrated recesses on the bottom of the target plate 70 to position the target plate 70 relative to the transfer area 3. Although the target plate 70 is shown in a simple manner in FIG. 1 and other figures, the target plate 70 may have a structure such as a wall. For example, the target plate 70 being used may have the same form as the detectable unit described in Japanese Unexamined Patent Application Publication No. 2025-64718.

As shown in the figure on the right in FIG. 1, the transport vehicle 1 includes a detection device 17 that detects the detection target 5 disposed on the transfer area 3. The detection device 17 may be constantly included in the transport vehicle 1 or may be temporarily included in the transport vehicle 1 during the training process. In the present embodiment, the detection device 17 is temporarily included in the transport vehicle 1 during the training process. More specifically, as shown in the figure on the right in FIG. 1, the transport vehicle 1 allows the holder 14 to hold the measurement unit U in place of the article W during the training process. The detection device 17 is disposed on the measurement unit U. In this manner, the transport vehicle 1 includes the detection device 17 by holding, using the holder 14, the measurement unit U on which the detection device 17 is disposed.

In the training process described below, the control system 4 in the present embodiment causes the transport vehicle 1 to learn the transfer position P corresponding to the transfer area 3. In this example, one of the multiple location information holders 21 is a target holder. The target holder is basically the location information holder 21 that is on the upstream side X1 relative to the learning target transfer area 3 and closest to the transfer area 3. The position indicated by the location information held by the target holder is a target position T.

In the examples shown in FIGS. 2, 3, and 5, three transfer areas 3 (specifically, a first transfer area 31, a second transfer area 32, and a third transfer area 33) are arranged in parallel in the travel direction X, and the first transfer area 31 is the learning target transfer area 3. The target plate 70 is thus disposed on the first transfer area 31. The location information holder 21 on the upstream side X1 relative to the first transfer area 31 and closest to the first transfer area 31 is the location information holder 21 holding the location information 0201. This location information holder 21 is thus a target holder. The location information 0201 held by this location information holder 21 indicates a target position T (refer to FIG. 3). In this example, the target plate 70 is disposed on the first transfer area 31. However, when the three transfer areas 3 are sequentially learned, the target plate 70 may be disposed on each of the three transfer areas 3.

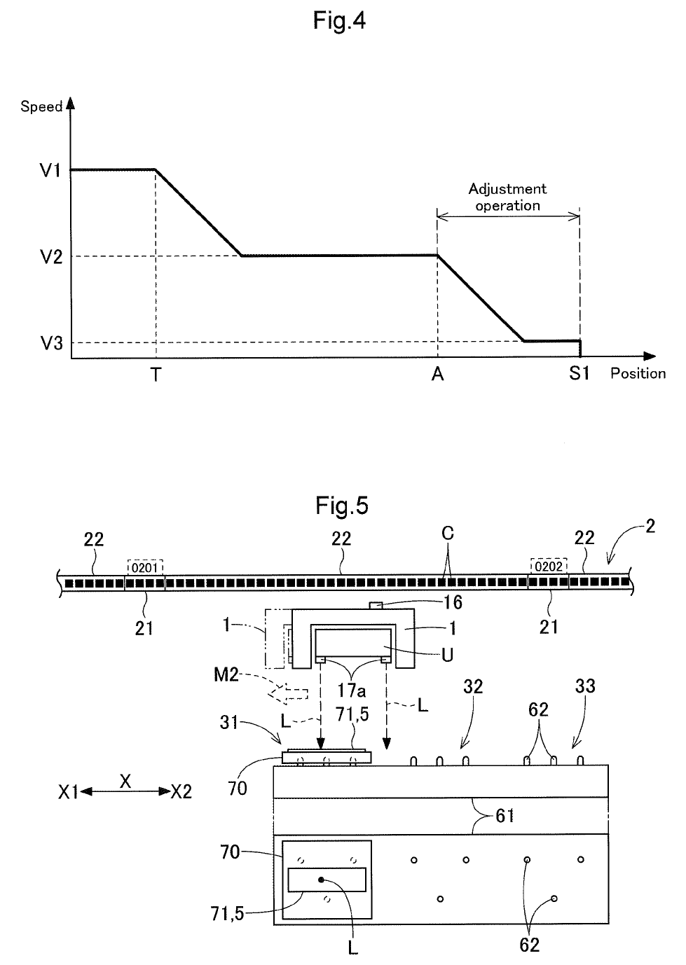

In the training process, the control system 4 specifies the learning target transfer area 3 in a manner associating (or linking) the learning target transfer area 3 with the target position T and causes the transport vehicle 1 to travel to the target holder (the location information holder 21 holding the information indicating the target position T associated with the specified transfer area 3). For example, the control system 4 sequentially specifies a learning target transfer area 3 from the multiple transfer areas 3 or specifies, as the learning target transfer area 3, a transfer area 3 selected by an operator. As shown in FIG. 4, the control system 4 in the present embodiment causes the transport vehicle 1 to travel to the target holder at a first speed V1. A second speed V2 (described later) is lower than the first speed V1, and a third speed V3 (described later) is lower than the second speed V2. When the location information obtaining device 16 included in the transport vehicle 1 obtains the location information of the target position T from the target holder, the control system 4 determines that the transport vehicle 1 has reached the target position T. In FIG. 2, the transport vehicle 1 that has reached the target position T is indicated by two-dot-dash lines.

In the present embodiment, the control system 4 reduces the traveling speed of the transport vehicle 1 based on the location information obtaining device 16 obtaining the location information of the target position T. More specifically, when determining that the transport vehicle 1 has reached the target position T, the control system 4 reduces the traveling speed of the transport vehicle 1. As shown in FIG. 4, the control system 4 in this example reduces the traveling speed of the transport vehicle 1 from the first speed V1 to the second speed V2 and then maintains the traveling speed of the transport vehicle 1 at the second speed V2.

After the location information obtaining device 16 obtains the location information of the target position T (specifically, after the transport vehicle 1 reaches the target position T), the control system 4 causes the transport vehicle 1 to perform an adjustment operation based on the detection device 17 detecting the detection target 5. In the present embodiment, the control system 4 reduces the traveling speed of the transport vehicle 1 based on the location information obtaining device 16 obtaining the location information of the target position T, before causing the transport vehicle 1 to perform an adjustment operation based on the detection device 17 detecting the detection target 5. In FIG. 2, the transport vehicle 1 that has performed forward movement M1 to a position at which the detection device 17 detects the detection target 5 (a detection position A in FIG. 4) is indicated by solid lines.

The adjustment operation adjusts the stop position of the transport vehicle 1. In the present embodiment, the control system 4 causes, in the adjustment operation, the transport vehicle 1 to travel at a traveling speed lower than the traveling speed at which the transport vehicle 1 travels after the location information obtaining device 16 obtains the location information of the target position T. In the present embodiment, the control system 4 reduces the traveling speed of the transport vehicle 1 from the first speed V1 to the second speed V2 based on the location information obtaining device 16 obtaining the location information of the target position T. In the adjustment operation, the control system 4 thus causes the transport vehicle 1 to travel at a traveling speed lower than the second speed V2. As shown in FIG. 4, the control system 4 in this example reduces the traveling speed of the transport vehicle 1 from the second speed V2 to the third speed V3 and then maintains the traveling speed of the transport vehicle 1 at the third speed V3.

In the adjustment operation, the control system 4 causes the transport vehicle 1 to move forward and backward based on the detection state of the detection target 5 detected by the detection device 17 until the detection state enters a preset state. As used herein, moving forward and backward refers to moving forward and backward as appropriate and includes moving only forward or only backward. In FIG. 3, two-dot-dash lines indicate the transport vehicle 1 at the detection position A (refer to FIG. 4), and solid lines indicate the transport vehicle 1 that has performed the forward movement M1 until the detection state of the detection target 5 detected by the detection device 17 enters the preset state. The preset state is a state in which the deviation from an ideal state of the positional relationship in the travel direction X between the transport vehicle 1 and the transfer area 3 is within a predetermined range. During the training process in the present embodiment, with the transport vehicle 1 at a first stop position S1 (described later), the holder 14 holding the measurement unit U is lowered to the transfer area 3. The preset state thus refers to a state in which the holder 14 holding the measurement unit U can be lowered to a target height without the measurement unit U coming into contact with the transfer area 3 or the target plate 70 disposed on the transfer area 3.

In the adjustment operation, the control system 4 causes the transport vehicle 1 to stop traveling in response to the detection state of the detection target 5 detected by the detection device 17 entering the preset state. The position at which the transport vehicle 1 is stopped in this manner is defined as the first stop position S1 (refer to FIGS. 3 and 4). In the present embodiment, as described above, the transport vehicle 1 at a site on the travel path 2 at which no location information holder 21 is disposed determines its position by causing the location information obtaining device 16 to obtain the information held by the codes C displayed on the code tape 22. In the present embodiment, the first stop position S1 is thus determined by the transport vehicle 1, and the control system 4 obtains the information indicating the first stop position S1 determined by the transport vehicle 1 from the transport vehicle 1.

The control system 4 records the position based on the first stop position S1 as the transfer position P. More specifically, the control system 4 sets the position based on the first stop position S1 as the transfer position P and records the set transfer position P. The position based on the first stop position S1 may be the same position as the first stop position S1 or may be a position different from the first stop position S1. The transfer position P recorded may be an absolute position or a relative position. The transfer position P is, for example, recorded in a storage 41 included in the host controller 40 (refer to FIG. 6). When causing the transport vehicle 1 to transfer articles W to and from the transfer area 3, the control system 4 obtains the transfer position P recorded for the transfer area 3 by, for example, referring to the storage 41 and causes the transport vehicle 1 to move to the obtained transfer position P (refer to the figure on the left in FIG. 1).

In the present embodiment, the recorded transfer position P is a relative position (specifically, a position relative to the target position T). More specifically, the control system 4 records the target position T and a target distance D from the target position T as information indicating the transfer position P. In this manner, during the training process, the travel distance from the target position T associated with the learning target transfer area 3 is learned. When the first stop position S1 is set as the transfer position P, the target distance D is the distance from the target position T to the first stop position S1, as shown in FIG. 3. However, when a position different from the first stop position S1 is set as the transfer position P, the target distance D is the distance from the target position T to the position different from the first stop position S1.

As shown in FIG. 2, the detection device 17 in the present embodiment includes a pair of optical sensors 17a spaced from each other in the travel direction X. Each of the pair of optical sensors 17a detects the detection target 5 by projecting sensing light L (a laser beam in this example) downward and receiving reflected light (reflected light from the detection target 5). More specifically, each of the pair of optical sensors 17a does not detect the detection target 5 when the reflected light intensity is lower than a predetermined threshold value, and detects the detection target 5 when the reflected light intensity is higher than or equal to the threshold value.

As described above, the detection target 5 in the present embodiment is the reflector 71 disposed on the upper surface of the target plate 70. The reflector 71 is disposed at the same position as the sensing light L in a horizontal direction perpendicular to the travel direction X. In the diagram (top view) of the platform 61 shown at the bottom of FIG. 2, the vertical direction in the figure is the horizontal direction perpendicular to the travel direction X. The reflector 71 has a predetermined width in the horizontal direction perpendicular to the travel direction X to accommodate a slight positional deviation of the sensing light L projected onto the reflector 71. As shown in FIG. 3, the reflector 71 has a length in the travel direction X greater than a detection interval defined by a spacing in the travel direction X between the pair of sensing light beams L projected by the pair of optical sensors 17a. The reflector 71 is thus in the form of a strip extending in the travel direction X.

As described above, after the location information obtaining device 16 obtains the location information of the target position T, the control system 4 causes the transport vehicle 1 to perform the adjustment operation based on the detection device 17 detecting the detection target 5. In the present embodiment, the reflector 71 is disposed as described above, and thus the control system 4 causes the adjustment operation to be started based on one of the pair of optical sensors 17a (specifically, the optical sensor 17a disposed on the downstream side X2) detecting the reflector 71 (refer to FIG. 2).

In the adjustment operation, the transport vehicle 1 is caused to perform forward movement M1 when the optical sensor 17a disposed on the downstream side X2 among the pair of optical sensors 17a detects the reflector 71 and the other optical sensor 17a does not detect the reflector 71 as shown in FIG. 2. In the adjustment operation, the transport vehicle 1 is caused to perform backward movement M2 when the optical sensor 17a disposed on the upstream side X1 among the pair of optical sensors 17a detects the reflector 71 and the other optical sensor 17a does not detect the reflector 71 as shown in FIG. 5. The control system 4 defines the preset state as a state in which both of the pair of optical sensors 17a detect the reflector 71. More specifically, when both of the pair of optical sensors 17a detect the reflector 71 as shown in FIG. 3, the control system 4 determines that the detection state of the detection target 5 detected by the detection device 17 has entered the preset state, and causes the transport vehicle 1 to stop traveling.

As shown in the figure on the right in FIG. 1, the transport vehicle 1 in the present embodiment can hold the measurement unit U using the holder 14. During the training process, the measurement unit U is held by the holder 14 in place of the article W. In the present embodiment, a flange similar to the flange formed on the upper part of the article W is formed on an upper part of the measurement unit U. The holder 14 holds the measurement unit U by supporting the flange formed on the upper part of the measurement unit U. For example, the measurement unit U has a weight and a center of gravity equal to (the same or substantially the same as) those of the article W.

The measurement unit U measures a relative positional relationship between the holder 14 and the transfer area 3 (hereafter simply referred to as the relative positional relationship). The measurement unit U measures the relative positional relationship with the transport vehicle 1 at the first stop position S1. More specifically, the measurement unit U measures the relative positional relationship with the transport vehicle 1 at the first stop position S1 and with the holder 14 holding the measurement unit U being lowered as indicated by dashed lines in the figure on the right in FIG. 1. The height of the holder 14 during measurement of the relative positional relationship (target height) is, for example, set to the transfer height described above or a height close to the transfer height, which is a height at which the measurement unit U does not come in contact with the transfer area 3 or the target plate 70 disposed on the transfer area 3.

In the present embodiment, the relative positional relationship between the measurement unit U and the target plate 70 is measured with a sensor included in the measurement unit U (e.g., a distance sensor, a tilt sensor, or a camera) to measure the relative positional relationship between the holder 14 holding the measurement unit U and the transfer area 3 on which the target plate 70 is disposed. Although details are not described, the measurement unit U measures at least the relative positional relationship in the travel direction X. The measurement unit U may further measure at least one of the relative positional relationship in the horizontal direction perpendicular to the travel direction X, the relative positional relationship in the vertical direction, the relative positional relationship (relative angle) about a vertical axis, the relative positional relationship (relative angle) about an axis extending in the travel direction X, and the relative positional relationship (relative angle) about an axis extending in the horizontal direction perpendicular to the travel direction X. For example, the measurement unit U being used may have the same form as the detection unit described in Japanese Unexamined Patent Application Publication No. 2025-64718.

The control system 4 derives a second stop position S2 based on the first stop position S1 and the relative positional relationship between the holder 14 and the transfer area 3 measured by the measurement unit U with the transport vehicle 1 at the first stop position S1. The second stop position S2 is a stop position of the transport vehicle 1 at which the holder 14 has an appropriate (ideal or near-ideal) positional relationship with the transfer area 3. More specifically, the control system 4 obtains, from measurement results obtained from the measurement unit U, a deviation of the first stop position S1 from an ideal position for transferring articles W to and from the transfer area 3 (a deviation in the travel direction X) and derives the second stop position S2 by correcting the first stop position S1 in a manner to reduce the deviation (e.g., to zero). The control system 4 records the derived second stop position S2 as the transfer position P (refer to the figure on the left in FIG. 1). In this manner, the training process in the present embodiment allows travel learning (learning of the first stop position S1 serving as a reference stop position for transfer learning) and transfer learning (learning of the second stop position S2) to be performed simultaneously.

### Second Embodiment

A transport facility according to a second embodiment will be described with reference to the drawings (FIGS. 7 - 10), focusing on its differences from the transport facility according to the first embodiment. The components not described in the embodiment are the same as those in the first embodiment, and denoted with the same reference signs and will not be described in detail.

In the present embodiment, as shown in FIG. 7, multiple markers 23 are arranged at discrete locations along the travel path 2 (specifically, in the travel direction X) at regular intervals with reference to the location information holders 21. In this example, nine markers 23 are arranged between the two location information holders 21 adjacent to each other in the travel direction X. For example, the markers 23 are arranged in a manner (e.g., size or color) that allows an operator to visually observe them. When performing the training process, the control system 4 specifies the learning target transfer area 3 in a manner associated with the target position T and with the ordinal position of the corresponding marker 23 relative to the target position T. For example, the operator identifies the ordinal position of the marker 23 relative to the target position T and records the information in the control system 4. Based on the information recorded in the control system 4 by the operator, the control system 4 specifies the learning target transfer area 3 in a manner associated with the target position T and with the ordinal position of the marker 23 relative to the target position T. In FIG. 7, circled numbers indicating the ordinal positions of the markers 23 relative to the target position T are shown below the markers 23 for ease of understanding.

In FIG. 7, the station (ST) number of the first transfer area 31 is ST001, the ST number of the second transfer area 32 is ST002, and the ST number of the third transfer area 33 is ST003. In the table shown in FIG. 7, for each transfer area 3, the associated target position T is shown in the Associated Address column, the number indicating the ordinal position of the marker 23 relative to the target position T is shown in the Marker Number column, and the target distance D recorded through the training process is shown in the Distance column. FIG. 7 represents the state before learning of the transfer position P for each transfer area 3, and thus no numerical value is shown in the Distance column.

In the present embodiment, when the center position of the transfer area 3 in the travel direction X is at the same position in the travel direction X as the N-th marker 23 relative to the target position T, the transfer area 3 is associated with the N-th marker 23. In the present embodiment, when the center position of the transfer area 3 in the travel direction X is between the N-th marker 23 and the (N + 1)th marker 23 relative to the target position T in the travel direction X, the transfer area 3 is associated with the N-th marker 23. In the example shown in FIG. 7, as indicated by dashed arrows, the center position of the first transfer area 31 (ST001) in the travel direction X is between the fourth marker 23 and the fifth marker 23 relative to the target position T(0201) in the travel direction X, the center position of the second transfer area 32 (ST002) in the travel direction X is between the seventh marker 23 and the eighth marker 23 relative to the target position T(0201) in the travel direction X, and the center position of the third transfer area 33 (ST003) in the travel direction X is between the zeroth marker 23 and the first marker 23 relative to the target position T(0202) in the travel direction X. The transfer areas 3 are thus associated with marker numbers as shown in the table in FIG. 7.

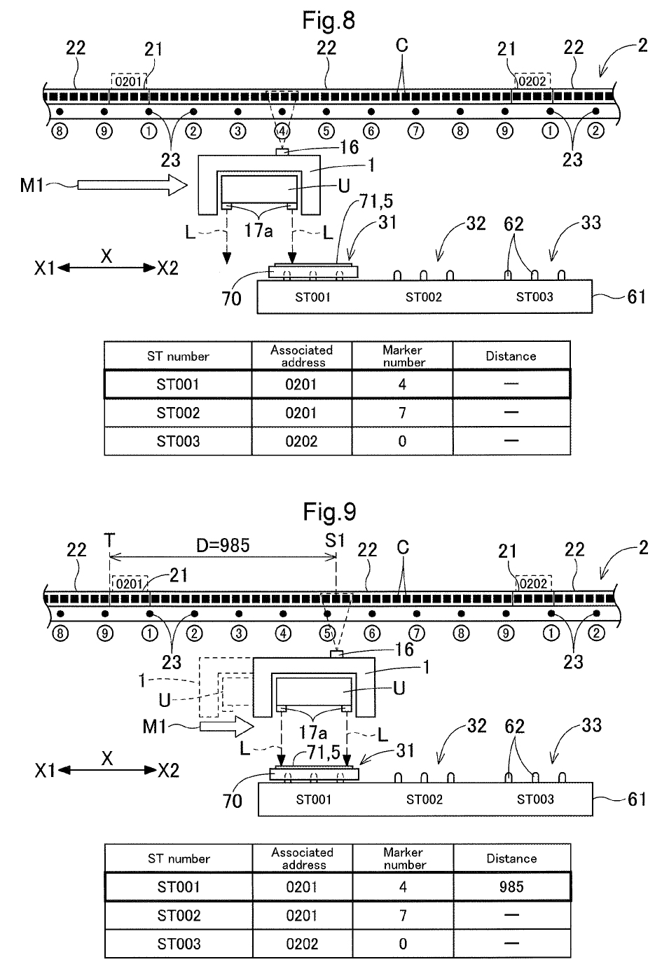

In the present embodiment, the control system 4 records, in the training process, the target position T, the number indicating the ordinal position of the marker 23 relative to the target position T, and the target distance D from the target position T as information indicating the transfer position P (refer to FIG. 9). The target position T and the number indicating the ordinal position of the marker 23 relative to the target position T are recorded before the training process is started. When the target distance D is recorded through the training process, values for all three items are recorded. Referring to FIGS. 8-10, the training process in the present embodiment when the first transfer area 31 is the learning target transfer area 3 will be described, focusing mainly on differences from the training process in the first embodiment.

As shown in FIG. 8, the target plate 70 is disposed on the first transfer area 31 that is the learning target transfer area 3. As described above, when performing the training process, the control system 4 in the present embodiment specifies the learning target transfer area 3 in a manner associated with the target position T and with the ordinal position of the corresponding marker 23 relative to the target position T. The control system 4 causes the transport vehicle 1 to travel to the position of the marker 23 associated with the specified transfer area 3. In this example, the first transfer area 31 is associated with 0201 as the target position T and also associated with 4 as the number indicating the ordinal position of the marker 23 relative to the target position T. As shown in FIG. 8, the control system 4 thus causes the transport vehicle 1 to travel to the position at which the fourth marker 23 from the position indicated by 0201 is disposed. In the present embodiment, an approximate position of the learning target transfer area 3 can be determined based on the ordinal position of the marker 23 relative to the target position T, and thus a position at which the traveling speed of the transport vehicle 1 is reduced from the first speed V1 can be set to a position on the downstream side X2 relative to the target position T.

FIG. 8 shows the transport vehicle 1 that has performed forward movement M1 to the position at which the fourth marker 23 from the position indicated by 0201 is disposed. In the present embodiment, the travel path 2 is indicated by map information including information indicating the positions of the markers 23 (e.g., information indicating distances from the target position T). For example, the map information is stored in the storage 41 (refer to FIG. 6). The control system 4 refers to the map information to determine the position of the marker 23 associated with the learning target transfer area 3 (hereafter referred to as an associated marker position) and causes the transport vehicle 1 to travel to the associated marker position.

The control system 4 causes the transport vehicle 1 to perform the adjustment operation based on the detection device 17 detecting the detection target 5 with the transport vehicle 1 at the associated marker position (specifically, with the transport vehicle 1 at the associated marker position after the location information obtaining device 16 obtains the location information of the target position T). In the example shown in FIG. 8, with the transport vehicle 1 at the associated marker position, only the optical sensor 17a disposed on the downstream side X2 among the pair of optical sensors 17a detects the reflector 71. The transport vehicle 1 thus performs forward movement M1 until the detection state of the detection target 5 detected by the detection device 17 enters the preset state (refer to FIG. 9). In the example shown in FIG. 9, the second stop position S2 is the same position as the first stop position S1. The value 985, which represents the target distance D, is recorded as information indicating the transfer position P of the first transfer area 31 (ST001).

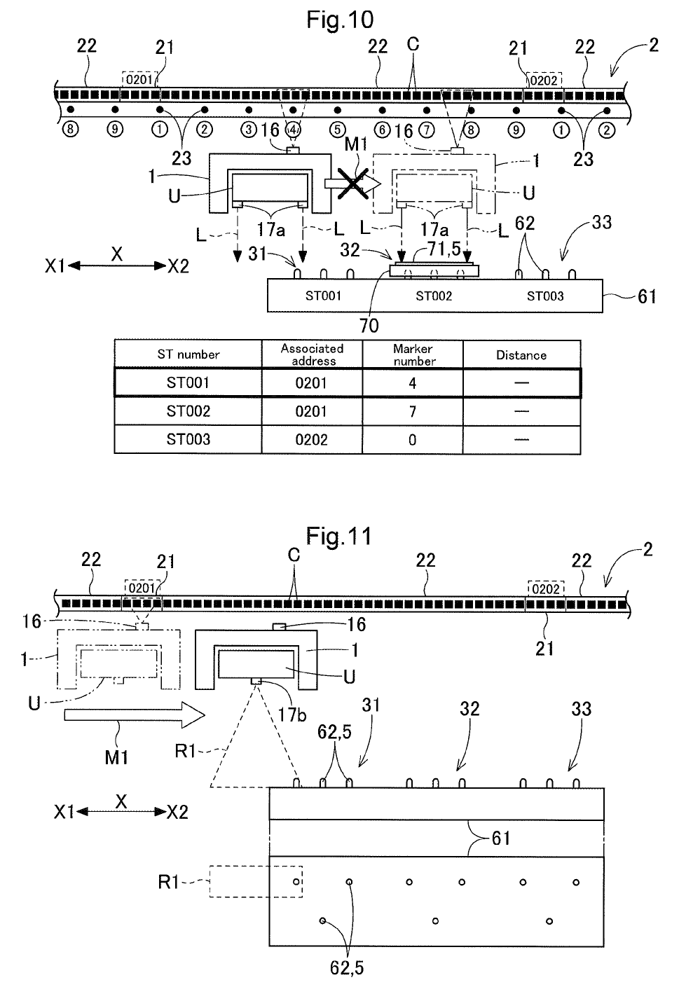

In the present embodiment, with the transport vehicle 1 at the associated marker position, when the detection device 17 detects no detection target 5, the control system 4 stops the training process without causing the transport vehicle 1 to perform the adjustment operation. For example, as shown in FIG. 10, when the target plate 70 is mistakenly disposed on the second transfer area 32 instead of the first transfer area 31, the detection device 17 in the transport vehicle 1 at the associated marker position detects no detection target 5. In such a case, when the training process is continued without being stopped, the transport vehicle 1 performs forward movement M1 to the second transfer area 32 as indicated by two-dot-dash lines in FIG. 10, and the target distance D for the second transfer area 32 may be mistakenly recorded as information indicating the transfer position P of the first transfer area 31. In contrast, when the training process is stopped in the above case, recording of such incorrect information can be avoided.

### Third Embodiment

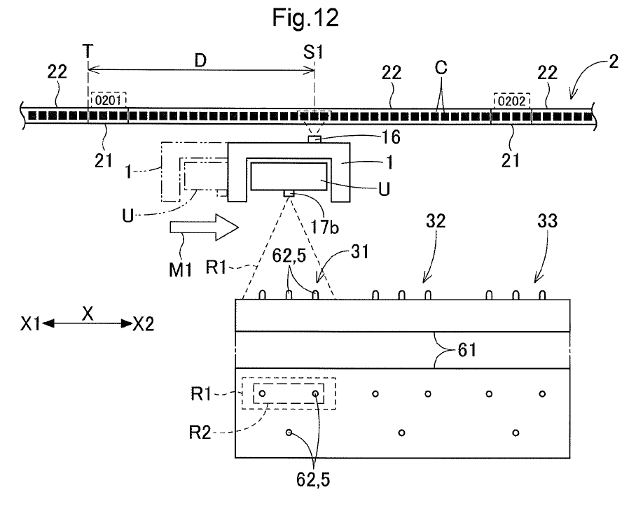

A transport facility according to a third embodiment will be described with reference to the drawings (FIGS. 11 and 12), focusing on its differences from the transport facility according to the first embodiment. The components not described in the present embodiment are the same as those in the first embodiment, and denoted with the same reference signs and will not be described in detail.

As shown in FIG. 11, the detection target 5 in the present embodiment includes the positioning pins 62 disposed on the surface of the transfer area 3 facing the transport vehicle 1. Unlike in the first embodiment, the detection target 5 in the present embodiment is thus constantly disposed on the transfer area 3. In the present embodiment, no target plate 70 is disposed on the transfer area 3. In the present embodiment, the detection device 17 is an imaging device 17b that can image the positioning pins 62. In the present embodiment, the positioning pins 62 correspond to a target object.

After the location information obtaining device 16 obtains the location information of the target position T, the control system 4 causes the transport vehicle 1 to perform the adjustment operation based on the detection device 17 detecting the detection target 5. In the present embodiment, the control system 4 causes the adjustment operation to be started based on any positioning pin 62 entering an imaging range R1 of the imaging device 17b (refer to FIG. 11). In this example, the size and the position of the imaging range R1 in the horizontal direction perpendicular to the travel direction X are set to allow two of the three positioning pins 62 aligned in the travel direction X to be imaged. The control system 4 causes the adjustment operation to be started based on one of the positioning pins 62 (specifically, one of the two positioning pins 62 aligned in the travel direction X and disposed on the upstream side X1) entering the imaging range R1 of the imaging device 17b.

The control system 4 defines the preset state as a state in which positioning pins 62 (two positioning pins 62 aligned in the travel direction X, as described below) are positioned within a set range R2 in the imaging range R1 of the imaging device 17b. More specifically, when the positioning pins 62 are positioned within the set range R2 in the imaging range R1 of the imaging device 17b, the control system 4 determines that the detection state of the detection target 5 detected by the detection device 17 has entered the preset state, and causes the transport vehicle 1 to stop traveling. In this example, as shown in FIG. 12, the set range R2 is sized in the travel direction X to allow the two positioning pins 62 aligned in the travel direction X to be simultaneously included within the set range R2. The control system 4 defines the preset state as a state in which both the two positioning pins 62 aligned in the travel direction X are positioned within the set range R2. More specifically, when both the two positioning pins 62 aligned in the travel direction X are positioned within the set range R2, the control system 4 determines that the detection state of the detection target 5 detected by the detection device 17 has entered the preset state, and causes the transport vehicle 1 to stop traveling.

In the present embodiment, the measurement unit U uses the imaging device 17b serving as the detection device 17 to measure the relative positional relationship between the holder 14 and the transfer area 3 (hereafter simply referred to as the relative positional relationship). More specifically, the measurement unit U includes the imaging device 17b as a sensor. In the present embodiment, the measurement unit U measures the relative positional relationship between the measurement unit U and at least one of the positioning pins 62 to measure the relative positional relationship between the holder 14 holding the measurement unit U and the transfer area 3 on which the positioning pins 62 are disposed. For example, the measurement unit U measures the relative positional relationship between the measurement unit U and the two positioning pins 62 aligned in the travel direction X. The positional relationship between the measurement unit U and the positioning pins 62 can be measured based on the positions of the positioning pins 62 in an image captured by the imaging device 17b.

In this example, the positioning pins 62 are target objects. However, the target object disposed on the surface of the transfer area 3 facing the transport vehicle 1 may not be the positioning pin 62. For example, a pattern drawn on the transfer area 3 or the shape of the transfer area 3 may serve as the target object to be imaged by the imaging device 17b. In other cases, the target plate 70 on which the target object to be imaged by the imaging device 17b may be disposed on the transfer area 3. Similarly, the target to be measured by the measurement unit U may not be the positioning pins 62.

### Other Embodiments

(1) In the first and second embodiments, the target plate 70 is disposed on the learning target transfer area 3. However, the present disclosure is not limited to this structure. In the first and second embodiments, the target plate 70 may not be disposed on the learning target transfer area 3. In this case, for example, the reflector 71 is directly disposed on the upper surface of the transfer area 3 (the surface facing the transport vehicle 1). In this case, for example, the measurement unit U measures the relative positional relationship between the measurement unit U and at least one of the positioning pins 62 to measure the relative positional relationship between the holder 14 holding the measurement unit U and the transfer area 3 on which the positioning pins 62 are disposed in the same manner as in the third embodiment. The measurement unit U used may have the same form as, for example, an inspection fixture described in Japanese Unexamined Patent Application Publication No. 2016-172607 or a teaching unit described in Japanese Unexamined Patent Application Publication No. 2021-187563.
(2) In the above embodiments, the transport vehicle 1 can hold the measurement unit U using the holder 14. However, the present disclosure is not limited to this structure. The transport vehicle 1 may allow the holder 14 to include the measurement unit U. In this case, for example, a sensor included in the measurement unit U (e.g., a distance sensor, a tilt sensor, or a camera) is directly attached to the holder 14.
(3) In the above embodiments, the detection device 17 is temporarily included in the transport vehicle 1 during the training process. However, the present disclosure is not limited to this structure. The detection device 17 may be constantly included in the transport vehicle 1.
(4) In the above embodiments, the control system 4 derives the second stop position S2 based on the first stop position S1 and the relative positional relationship between the holder 14 and the transfer area 3 measured by the measurement unit U with the transport vehicle 1 at the first stop position S1, and records the second stop position S2 as the transfer position P. However, the present disclosure is not limited to this structure. The control system 4 may record the first stop position S1 as the transfer position P without measurement by the measurement unit U. In this case, the transport vehicle 1 may or may not allow the holder 14 to hold the measurement unit U and may or may not allow the holder 14 to include the measurement unit U.
(5) In the above embodiments, the controller 10 included in each transport vehicle 1 and the host controller 40 implement the control system 4. However, the present disclosure is not limited to this structure. The host controller 40 alone may implement the control system 4. The transport facility 100 may include no host controller 40, and the controllers 10 in the transport vehicles 1 that can communicate with each other may cooperate to implement the control system 4.
(6) The structure described in each of the above embodiments may be combined with the structures described in other embodiments (including combinations of the other embodiments described as other embodiments) unless any contradiction arises. The embodiments described herein are mere examples in all respects. The embodiments may be modified variously without departing from the spirit and scope of the disclosure.

### Overview of Present Embodiment

An overview of the transport facility according to the embodiments described above is provided below.

A transport facility includes a transport vehicle that transports an article, a travel path along which the transport vehicle travels, a transfer area to and from which the transport vehicle stopped at a transfer position on the travel path transfers the article, a control system that controls the transport vehicle, and a plurality of location information holders arranged at discrete locations along the travel path. The plurality of location information holders hold location information of positions on the travel path. The transport vehicle includes a location information obtaining device that obtains the location information from the plurality of location information holders, and a detection device that detects a detection target disposed on the transfer area. One of the plurality of location information holders is a target holder. The location information held by the target holder indicates a target position. In a training process to cause the transport vehicle to learn the transfer position corresponding to the transfer area, the control system specifies a learning target transfer area in a manner associated with the target position, causes the transport vehicle to travel to the target holder and perform an adjustment operation for adjusting a stop position of the transport vehicle based on the detection device detecting the detection target after the location information obtaining device obtains the location information of the target position, causes the transport vehicle to stop traveling in response to a detection state entering a preset state , the detection state being a state of the detection device detecting the detection target, and records, as the transfer position, a position based on a first stop position that is a position at which the transport vehicle has stopped in response to the detection state entering the preset state.

This structure can determine the appropriate transfer position through the training process when no location information holder is aligned with the transfer position corresponding to the transfer area. More specifically, in the training process, after the location information obtaining device obtains location information of the target position, the detection device detects the detection target disposed on the transfer area to locate the transfer area. The adjustment operation is then performed to adjust the stop position of the transport vehicle to cause the transport vehicle to stop traveling based on the detection state of the detection target detected by the detection device entering the preset state. This allows determining and recording the position based on this stop position, which is the first stop position, as the transfer position. When the transport vehicle transfers articles to and from a transfer area, the transport vehicle can determine the transfer position corresponding to the transfer area based on recording results obtained through the training process.

As described above, this structure can determine the appropriate transfer position corresponding to a transfer area when no location information holder is aligned with the transfer position.

The adjustment operation may include causing the transport vehicle to travel at a traveling speed lower than a traveling speed at which the transport vehicle travels after the location information obtaining device obtains the location information of the target position and cause the transport vehicle to move forward and backward based on the detection state until the detection state enters the preset state.

This structure can cause the transport vehicle to move forward and backward at a relatively low traveling speed in the adjustment operation, thus allowing the transport vehicle to appropriately stop at the position at which the detection state of the detection target detected by the detection device enters the preset state. The appropriate transfer position can be determined based on the first stop position, which is the position at which the transport vehicle appropriately stopped in the above manner stops.

The transport vehicle may include a holder that holds the article. The holder may hold a measurement unit or include a measurement unit. The measurement unit may measure a relative positional relationship between the holder and the transfer area. The control system may record, as the transfer position, a second stop position based on the first stop position and the relative positional relationship between the holder and the transfer area measured by the measurement unit with the transport vehicle at the first stop position. The second stop position is a stop position of the transport vehicle at which stop position the holder and the transfer area have an appropriate positional relationship.

This structure can determine the transfer position with higher accuracy based on measurement results obtained from the measurement unit.

The transport facility may further include a plurality of markers arranged at discrete locations at regular intervals along the travel path with reference to the location information holders. In the training process, the control system may specify the learning target transfer area in a manner associated with the target position and with an ordinal position of a marker corresponding to the learning target transfer area among the plurality of markers. The ordinal position is a position relative to the target position. The control system may record, as information indicating the transfer position, the target position, a number indicating the ordinal position of the marker relative to the target position, and a distance from the target position.

Unlike this structure, a learning target transfer area may be specified in a manner associated with a target position alone. To locate the appropriate transfer area in this case, the traveling speed of the transport vehicle is to be reduced when, for example, the transport vehicle reaches the target position. In contrast, when performing the training process, this structure specifies the learning target transfer area in a manner associated with the target position and with the ordinal position of the corresponding marker relative to the target position, thus allowing the traveling speed of the transport vehicle to be reduced at a position that is closer to the transfer area than the target position is (e.g., a position between the target position and the marker associated with the learning target transfer area). This shortens the time for the training process. This structure can specify the learning target transfer area in a manner associated with the ordinal position of the corresponding marker relative to the target position. This also facilitates avoiding mistakenly performing the training process on a transfer area corresponding to a marker at a different ordinal position.

The detection target may include a reflector disposed on a surface of the transfer area. The surface faces the transport vehicle. The detection device may include a pair of optical sensors spaced from each other in a direction along the travel path. The control system may cause the adjustment operation to be started based on one of the pair of optical sensors detecting the reflector and define, as the preset state, a state of both the pair of optical sensors detecting the reflector.

In this structure, when the detection target is a reflector disposed on the surface of the transfer area facing the transport vehicle, the adjustment operation can be appropriately started, and the transport vehicle can be appropriately stopped at a position at which the detection state of the detection target detected by the detection device enters the preset state.

The detection target may be a target object disposed on a surface of the transfer area. The surface faces the transport vehicle. The detection device may be an imaging device that images the target object. The control system may cause the adjustment operation to be started based on the target object entering an imaging range of the imaging device and define, as the preset state, a state of the target object being positioned within a set range in the imaging range of the imaging device.

In this structure, when the detection target is a target object disposed on the surface of the transfer area facing the transport vehicle, the adjustment operation can be appropriately started, and the transport vehicle can be appropriately stopped at a position at which the detection state of the detection target detected by the detection device enters the preset state.

The transport facility according to one or more embodiments of the disclosure produces at least one of the effects described above.

What is claimed is:

1. A transport facility, comprising:
a transport vehicle configured to transport an article;
a travel path along which the transport vehicle travels;
a transfer area to and from which the transport vehicle stopped at a transfer position on the travel path transfers the article;
a control system configured to control the transport vehicle; and
a plurality of location information holders arranged at discrete locations along the travel path, the plurality of location information holders holding location information of positions on the travel path,
wherein the transport vehicle comprises:
a location information obtaining device configured to obtain the location information from the plurality of location information holders, and
a detection device configured to detect a detection target disposed on the transfer area,
wherein one of the plurality of location information holders is a target holder, the location information held by the target holder indicating a target position, and
wherein in a training process to cause the transport vehicle to learn the transfer position corresponding to the transfer area, the control system is configured to specify a learning target transfer area in a manner associated with the target position, cause the transport vehicle to travel to the target holder and perform an adjustment operation for adjusting a stop position of the transport vehicle based on the detection device detecting the detection target after the location information obtaining device obtains the location information of the target position, cause the transport vehicle to stop traveling in response to a detection state entering a preset state, the detection state comprising a state of the detection device detecting the detection target, and record, as the transfer position, a position based on a first stop position that is a position at which the transport vehicle is stopped in response to the detection state entering the preset state.

2. The transport facility according to claim 1, wherein:
the adjustment operation comprises causing the transport vehicle to travel at a traveling speed lower than a traveling speed at which the transport vehicle travels after the location information obtaining device obtains the location information of the target position and causes the transport vehicle to move forward and backward based on the detection state until the detection state enters the preset state.

3. The transport facility according to claim 1, wherein:
the transport vehicle comprises a holder configured to hold the article, the holder configured to hold a measurement unit or comprising a measurement unit,
the measurement unit is configured to measure a relative positional relationship between the holder and the transfer area, and
the control system records, as the transfer position, a second stop position based on the first stop position and the relative positional relationship between the holder and the transfer area measured by the measurement unit with the transport vehicle at the first stop position, the second stop position being a stop position of the transport vehicle at which stop position the holder and the transfer area have an appropriate positional relationship.

4. The transport facility according to claim 1, further comprising:
a plurality of markers arranged at discrete locations at regular intervals along the travel path with reference to the location information holders,
wherein in the training process, the control system specifies the learning target transfer area in a manner associated with the target position and with an ordinal position of a marker corresponding to the learning target transfer area among the plurality of markers, the ordinal position being a position relative to the target position, and records, as information indicating the transfer position, the target position, a number indicating the ordinal position of the marker relative to the target position, and a distance from the target position.

5. The transport facility according to claim 1, wherein:
the detection target comprises a reflector disposed on a surface of the transfer area, the surface facing the transport vehicle,
the detection device comprises a pair of optical sensors spaced from each other in a direction along the travel path, and
the control system causes the adjustment operation to be started based on one of the pair of optical sensors detecting the reflector and defines, as the preset state, a state of both the pair of optical sensors detecting the reflector.

6. The transport facility according to claim 1, wherein:
the detection target is a target object disposed on a surface of the transfer area, the surface facing the transport vehicle,
the detection device is an imaging device configured to image the target object, and
the control system causes the adjustment operation to be started based on the target object entering an imaging range of the imaging device and defines, as the preset state, a state of the target object being positioned within a set range in the imaging range of the imaging device.
